(19) United States
(12) Patent Application Publication
(10) Pub. No.: US 2008/0093661 A1
(43) Pub. Date: Apr. 24, 2008

(54) NON-VOLATILE MEMORY DEVICE HAVING A CHARGE TRAPPING LAYER AND METHOD FOR FABRICATING THE SAME

(75) Inventors: Moon Sig Joo, Icheon-si (KR); Hong Seon Yang, Yongsin-si (KR); Jae Chul Om, Icheon-si (KR); Seung Ho Pyi, Yongin-si (KR); Seung Ryong Lee, Seoul (KR); Yong Top Kim, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/770,683

(22) Filed: Jun. 28, 2007

(30) Foreign Application Priority Data
Oct. 23, 2006 (KR) 10-2006-0103010

(51) Int. Cl. H01L 29/792; H01L 21/336

(52) U.S. Cl. 257/324; 438/257; 257/E29.309; 257/E21.423

(57) ABSTRACT

A non-volatile memory device comprises a substrate, a tunneling layer over the substrate, a charge trapping layer comprising a stoichiometric silicon nitride layer and a silicon-rich silicon nitride layer over the tunneling layer, a blocking layer over the charge trapping layer, and a control gate electrode over the blocking layer.

### CROSS-REFERENCES TO RELATED APPLICATIONS

The present application claims priority to Korean patent application number 10-2006-103010, filed on Oct. 23, 2006, which is incorporated by reference in its entirety.

### BACKGROUND OF THE INVENTION

The present invention relates to a non-volatile memory device and, more particularly, to a non-volatile memory device having a charge trapping layer and a method of fabricating the non-volatile memory device.

Semiconductor memory devices for storing data are categorized into volatile and non-volatile memory devices. When power is removed, volatile memory devices lose stored data, but non-volatile memory devices retain stored data. Accordingly, non-volatile memory devices are widely utilized in many devices including cellular phones, memory cards for storing music and/or image data, and other devices which may be placed under adverse power conditions, e.g., a discontinuous power supply, an intermittent power connection, or low power consumption.

The cell transistor of such a non-volatile memory device has a stacked gate structure. The stacked gate structure includes a gate insulating layer, a floating gate electrode, an intergate dielectric layer and a control gate electrode sequentially stacked on a channel region of a cell transistor. However, the stacked gate structure has difficulty improving an integration level of a memory device due to various interferences caused by the increased integration level. Accordingly, a non-volatile memory device having a charge trapping layer has been developed.

The non-volatile memory device having a charge trapping layer comprises a silicon substrate having a channel region therein, and a tunneling layer, a charge trapping layer, a blocking layer and a control gate electrode sequentially stacked on the silicon substrate. Such a structure is referred to as a SONOS (Silicon-Oxide-Nitride-Oxide-Silicon) structure or MONOS (Metal-Oxide-Nitride-Oxide-Silicon) structure.

FIG. 1 is a cross-sectional view illustrating a non-volatile memory device having a conventional charge trapping layer. Referring to FIG. 1, a tunneling insulating layer 110 is formed on a semiconductor substrate 100, e.g., a silicon substrate. A pair of impurity regions 102 (e.g., source/drain regions) are disposed in the semiconductor substrate 100. The impurity regions 102 are spaced apart from each other. A channel region 104 is disposed between the impurity regions 102. A silicon nitride layer 120 formed as a charge trapping layer is disposed on the tunneling insulating layer 110. A blocking insulating layer 130 is disposed on the silicon nitride layer 120. A control gate electrode 140 is disposed on the blocking insulating layer 130.

A process for operating the non-volatile memory device having such a structure will be described in detail. The control gate electrode 140 is positively charged and a predetermined bias is applied to the impurity region 102. As a result, electrons are trapped from the substrate 100 in a trap site of the silicon nitride layer 120 serving as a charge trapping layer. Such a phenomenon performs a write operation in each memory cell or a programming operation on the memory cell. Similarly, the control gate electrode 140 is negatively charged and a predetermined bias is applied to the impurity region 102. As a result, holes are trapped from the substrate 100 in the trap site of the silicon nitride layer 120 serving as a charge trapping layer. The trapped holes are then recombined with the electrons present in the trap site. This phenomenon performs an erase operation on the programmed memory cell.

The non-volatile memory device having the conventional charge trapping layer has a disadvantage of low erase speed. More specifically, upon programming the non-volatile memory device having the structure described above, electrons are trapped into a deep trap site, which is spaced relatively far from a conduction band of the silicon nitride layer 120. For this reason, a relatively high voltage is needed to erase the device. When a high voltage is applied to the control gate electrode 140 to perform an erase operation, backward tunneling occurs in which electrons present in the control gate electrode 140 pass through the blocking insulating layer 130. Thus, cells are inadvertently programmed, and an error, e.g., an increase in threshold voltage, occurs.

To prevent backward tunneling of electrons in the control gate electrode 140, a non-volatile memory device structure has been developed that uses high dielectric (high-k) materials such as aluminum oxide (Al₂O₃) for the blocking insulating layer 130, and uses metal gates having a large work function for the control gate electrode 140. Such a structure is referred to as MANOS (Metal-Alumina-Nitride-Oxide-Silicon). This structure prevents backward tunneling, but fails to secure a desired erase speed and has a limitation in realizing a sufficiently low threshold voltage even after an erase operation.

### BRIEF SUMMARY OF THE INVENTION

In one embodiment, a non-volatile memory device comprises a substrate; a tunneling layer disposed over the substrate; a charge trapping layer comprising a stoichiometric silicon nitride layer and a silicon-rich silicon nitride layer sequentially disposed over the tunneling layer; a blocking layer disposed over the charge trapping layer; and a control gate electrode disposed over the blocking layer.

In another embodiment, a non-volatile memory device comprises a substrate; a tunneling layer disposed over the substrate; a charge trapping layer comprising a first stoichiometric silicon nitride layer, a silicon-rich silicon nitride layer and a second stoichiometric silicon nitride layer sequentially disposed over the tunneling layer; a blocking layer disposed over the charge trapping layer for blocking migration of charges; and a control gate electrode disposed over the blocking layer.

In another embodiment, a non-volatile memory device comprises a substrate; a tunneling layer disposed over the substrate; a charge trapping layer comprising a silicon oxynitride layer and a silicon-rich silicon nitride layer sequentially disposed over the tunneling layer; a blocking layer disposed over the charge trapping layer for blocking migration of charges; and a control gate electrode disposed over the blocking layer.

In another embodiment, a non-volatile memory device comprises a substrate; a tunneling layer disposed over the substrate; a charge trapping layer comprising a first silicon oxynitride layer, a silicon-rich silicon nitride layer, and a second silicon oxynitride layer sequentially disposed over the tunneling layer; a blocking layer disposed over the charge trapping layer for blocking migration of charges; and a control gate electrode disposed over the blocking layer.

In another embodiment, a method for fabricating a non-volatile memory device comprises: forming a tunneling layer over a substrate; forming a stoichiometric silicon nitride layer over the tunneling layer; forming a silicon-rich silicon nitride layer over the stoichiometric silicon nitride layer; forming a blocking layer over the silicon-rich silicon nitride layer; and forming a control gate electrode over the blocking layer.

In another embodiment, a method for fabricating a non-volatile memory device comprises: forming a tunneling layer over a substrate; forming a first stoichiometric silicon nitride layer over the tunneling layer; forming a silicon-rich silicon nitride layer over the first stoichiometric silicon nitride layer; forming a second stoichiometric silicon nitride layer over the silicon-rich silicon nitride layer; forming a blocking layer over the second stoichiometric silicon nitride layer; and forming a control gate electrode over the blocking layer.

In another embodiment, a method for fabricating a non-volatile memory device comprises: forming a tunneling layer over a substrate; forming a first silicon oxynitride layer over the tunneling layer; forming a silicon-rich silicon nitride layer over the first silicon oxynitride layer; forming a blocking layer over the silicon-rich silicon nitride layer; and forming a control gate electrode over the blocking layer.

In another embodiment, a method for fabricating a non-volatile memory device comprises: forming a tunneling layer over a substrate; forming a first silicon oxynitride layer over the tunneling layer; forming a silicon-rich silicon nitride layer over the first silicon oxynitride layer; forming a second silicon oxynitride layer over the silicon-rich silicon nitride layer; forming a blocking layer over the second silicon oxynitride layer; and forming a control gate electrode over the blocking layer.

### BRIEF DESCRIPTION OF THE DRAWINGS

FIG. 1 is a cross-sectional view illustrating a non-volatile memory device having a conventional charge trapping layer.

FIG. 2 is a cross-sectional view illustrating a non-volatile memory device having a charge trapping layer according to one embodiment of the present invention.

FIG. 3 is a graph showing Auger Electron Spectroscopy (AES) of the charge trapping layer of the non-volatile memory device shown in FIG. 2.

FIG. 4 is a cross-sectional view illustrating a non-volatile memory device having a charge trapping layer according to another embodiment of the present invention.

FIG. 5 is a graph showing programming characteristics of a non-volatile memory device having a charge trapping layer according to the present invention.

FIG. 6 is a graph showing erasing characteristics of a non-volatile memory device having a charge trapping layer according to the present invention.

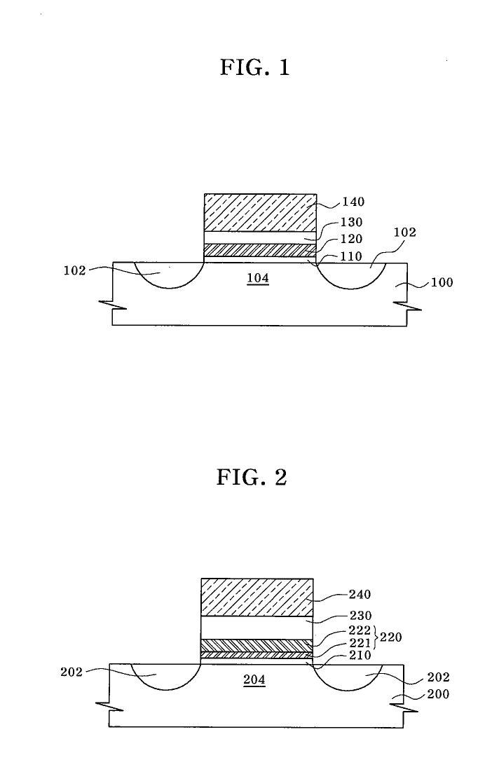

### DETAILED DESCRIPTION OF THE INVENTION

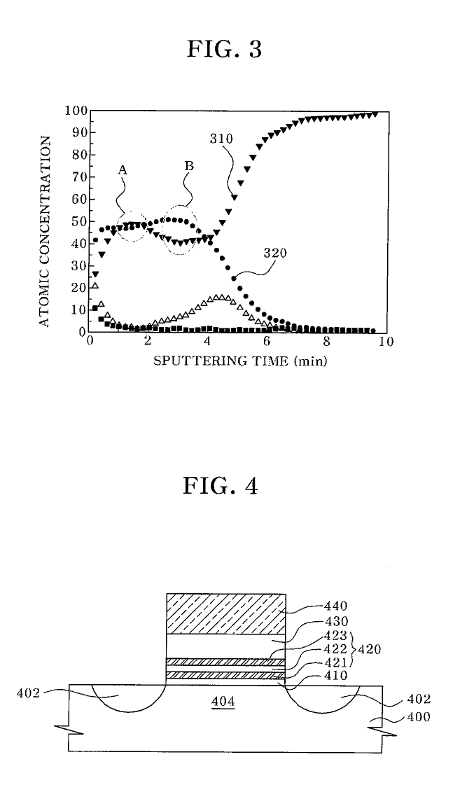

FIG. 2 is a cross-sectional view illustrating a non-volatile memory device having a charge trapping layer according to one embodiment of the present invention. FIG. 3 is a graph showing Auger Electron Spectroscopy (AES) of the charge trapping layer of the non-volatile memory device shown in FIG. 2. Referring to FIG. 2, the non-volatile memory device according to one embodiment of the present invention includes a tunneling layer 210, a charge trapping layer 220, a blocking layer 230, and a control gate electrode 240 sequentially disposed on a substrate 200. The charge trapping layer 220 consists of a stoichiometric silicon nitride (Si₃N₄) layer 221 and a silicon-rich silicon nitride layer 222 stacked sequentially. The substrate 200 includes a pair of impurity regions 202 spaced apart from each other with a channel region 204 disposed therebetween. The substrate 200 may be a silicon substrate or silicon on insulator (SOI). The impurity regions 202 are conventional source/drain regions.

The tunneling layer 210 is an insulating layer. Under predetermined conditions, charge carriers such as electrons or holes can be injected through the tunneling layer 210 into the charge trapping layer 220. The tunneling layer 210 may be formed of silicon oxide (SiO₂). The tunneling layer 210 has a thickness of about 20 Å to 60 Å. When the tunneling layer 210 has an excessively small thickness, it may deteriorate due to repeated tunneling of charge carriers, thereby adversely impacting the stability of a memory device. In contrast, when the tunneling layer 210 has an excessively large thickness, tunneling of charge carriers cannot be favorably performed.

The charge trapping layer 220 is an insulating layer which traps electrons or holes introduced through the tunneling layer 210. The charge trapping layer 220 is a double-layer including the stoichiometric silicon nitride (Si₃N₄) layer 221 and the silicon-rich silicon nitride layer 222 which are sequentially laminated. The stoichiometric silicon nitride (Si₃N₄) layer 221 has a thickness of about 20 Å to 60 Å. The silicon-rich silicon nitride layer 222 has a thickness of about 40 Å to 120 Å. Accordingly, the total thickness of the charge trapping layer 220 may be about 60 Å to 180 Å. The stoichiometric silicon nitride (Si₃N₄) layer 221 does not form bonds between silicon molecules. However, since the silicon-rich silicon nitride layer 222 forms bonds between silicon molecules, a hole trap readily occurs therein. As a result, a removal speed of the trapped electrons is increased, an erase speed is increased, and a sufficiently low threshold voltage is obtained after erasing. The ratio of silicon and nitrogen in the stoichiometric silicon nitride (Si₃N₄) layer 221 is approximately 1:1.2 to 1:1.5, and preferably about 1:1.33. The ratio of silicon and nitrogen in the silicon-rich silicon nitride layer 222 is approximately 0.85:1 to 3:1, and preferably about 1:1.

The type and content of the atoms in the charge trapping layer 210 disposed on the tunneling layer 210 were evaluated using AES (Auger Electron Spectroscopy). The result is shown in FIG. 3. It can be confirmed from FIG. 3 that the ratio of silicon 310 to nitrogen 320 is about 1:1, for a sputtering time of about 1 to 2 min (designated by “A” in FIG. 3). FIG. 3 also shows that the ratio is about 3:4 for a sputtering time of about 3 min (designated by “B” in FIG. 3). In other words, the stoichiometric silicon nitride (Si₃N₄) layer 221 disposed directly on the charge trapping layer 210 contains silicon and nitrogen at a ratio of approximately 3:4, while the silicon-rich silicon nitride layer 222 disposed on the stoichiometric silicon nitride (Si₃N₄) layer 221 contains silicon and nitrogen at a ratio of approximately 1:1.

According to another embodiment of the present invention, a silicon oxynitride (SiON) layer may be used instead of the stoichiometric silicon nitride (Si₃N₄) layer 221. The silicon oxynitride (SiON) layer exhibits superior trapping capabilities and, thus, shows improved retention characteristics when compared to the stoichiometric silicon nitride (Si₃N₄) layer.

The blocking layer 230 is an insulating layer for blocking migration of charges from the charge trapping layer 220 to the control gate electrode 240. The blocking layer 230 includes a silicon oxide (SiO₂) layer deposited by chemical vapor deposition (CVD) or an aluminum oxide (Al₂O₃) layer. Alternatively, the blocking layer 230 includes a high-dielectric insulating layer, e.g., a hafnium oxide (HfO₂) layer, a hafnium aluminum oxide (HfAlO) layer, a zirconium oxide (ZrO₂) layer, or combinations thereof. When an aluminum oxide (Al₂O₃) layer is used as the blocking layer 230, the thickness of the aluminum oxide (Al₂O₃) layer is approximately 50 Å to 300 Å.

The control gate electrode 240 allows electrons or holes to be trapped from the channel region 204 in the substrate 200 into a trap site in the charge trapping layer 220. The control gate electrode 240 may be a polysilicon layer or a metallic layer. When the control gate electrode 240 is a polysilicon layer, it has a silicon-oxide-nitride-oxide-silicon (SONOS) structure. When the control gate electrode 240 is a metallic layer, it has a metal-oxide-nitride-oxide-silicon (MONOS) structure. When the control gate electrode 240 and the blocking layer 230 are a metallic layer and an aluminum oxide (Al₂O₃) layer, respectively, they have a metal-aluminum-nitride-oxide-silicon (MANOS) structure. The polysilicon layer is doped with n-type impurities. When a metallic layer is used as the control gate electrode 240 to form the MONOS or MANOS structure, the metallic layer has a work function of about 4.5 eV or higher. Examples of suitable metallic layers include a titanium nitride (TiN) layer, a tantalum nitride (TaN) layer, a hafnium nitride (HfN) layer, a tungsten nitride (WN) layer and combinations thereof. To reduce the resistance of a control gate line, a low-resistance layer (not shown) may be disposed on the control gate electrode 240. The low-resistance layer varies depending upon the material used for the control gate electrode 240 which is determined by the reactivity on the interface between the control gate electrode 240 and the low-resistance layer.

A method for fabricating such a non-volatile memory device will be described in detail. Impurity regions 202 and a channel region 204 between the impurity regions 202 are formed in a substrate 200. A tunneling layer 210 is then formed on the substrate 200. The tunneling layer 210 is formed of a silicon oxide layer having a thickness of about 20 Å to 60 Å. A charge trapping layer 220 is formed on the tunneling layer 210. The formation of the charge trapping layer 220 is performed by forming a stoichiometric silicon nitride (Si₃N₄) layer 221 and a silicon-rich silicon nitride layer 222 sequentially on the tunneling layer 210. According to another embodiment of the present invention, a silicon oxynitride layer may be formed instead of the stoichiometric silicon nitride (Si₃N₄) layer 221.

The formation of the stoichiometric silicon nitride (Si₃N₄) layer 221 is performed using atomic layer deposition (ALD) or chemical vapor deposition (CVD). The thickness of the stoichiometric silicon nitride (Si₃N₄) layer 221 is about 20 Å to 60 Å. In the stoichiometric silicon nitride (Si₃N₄) layer 221, the ratio of silicon to nitrogen is approximately 1:1.2 to 1:1.5, and preferably about 1:1.33. Similarly, the formation of the silicon-rich silicon nitride layer 222 is performed using atomic layer deposition (ALD) or chemical vapor deposition (CVD). The thickness of the silicon-rich silicon nitride layer 222 is about 40 Å to 120 Å. As a result, the total thickness of the charge trapping layer 220 is about 60 Å to 180 Å. In the silicon-rich silicon nitride layer 222, the ratio of silicon to nitrogen is approximately 0.85:1 to 3:1, and preferably about 1:1. The ratio can be adjusted to a desired level by controlling a flow rate of a silicon source gas (e.g., dichlorosilane (DCS, SiCl₂H₂)), or a nitrogen source gas (e.g., NH₃).

After formation of the charge trapping layer 220 having a double-layered structure, a blocking layer 230 is formed on the charge trapping layer 220. The formation of the blocking layer 230 is performed by depositing an oxide layer by chemical vapor deposition (CVD). Alternatively, the blocking layer 230 may be formed of an aluminum oxide (Al₂O₃) layer to improve device characteristics. The blocking layer 230 is formed by depositing an aluminum oxide (Al₂O₃) layer to a thickness of about 50 Å to 300 Å and subjecting the deposited aluminum oxide layer to densification by rapid thermal processing (RTP). Alternatively, the blocking layer 230 may include a high-dielectric insulating layer, e.g., a hafnium oxide (HfO₂) layer, a hafnium aluminum oxide (HfAlO) layer, a zirconium oxide (ZrO₂) layer, or combinations thereof.

A control gate electrode 240 is formed on the blocking layer 230. If necessary, a low-resistance layer (not shown) may be formed on the control gate electrode 240. The control gate electrode 240 may be formed of a polysilicon layer or a metallic layer. When a polysilicon layer is used as the control gate electrode 240, the polysilicon layer may be doped with n-type impurities. When a metallic layer is used as the control gate electrode 240, the metallic layer may be a metallic layer having a work function of about 4.5 eV or higher. Examples of suitable metallic layers include a titanium nitride (TiN) layer, a tantalum nitride (TaN) layer, a hafnium nitride (HfN) layer, a tungsten nitride (WN) layer and combinations thereof.

After the tunneling layer 210, the charge trapping layer 220 (including the nitride layer 221 and the silicon-boron-nitride (SiBN) layer 222), the blocking layer 230, and the control gate electrode 240 are formed sequentially on the substrate 200, the resulting structure is subjected to common patternization using a hard mask layer pattern.

FIG. 4 is a cross-sectional view illustrating a non-volatile memory device having a charge trapping layer according to another embodiment of the present invention. Referring to FIG. 4, the non-volatile memory device according to one embodiment of the present invention includes a tunneling layer 410, a charge trapping layer 420, a blocking layer 430 and a control gate electrode 440 sequentially deposited on a substrate 400 where a channel region 404 is formed between an impurities region 402. The non-volatile memory device of this embodiment is different from that of the previous embodiment. Specifically, the charge trapping layer 420 of the present embodiment has a triple-layered structure in which a first stoichiometric silicon nitride (Si₃N₄) layer 421, a silicon-rich silicon nitride layer 422, and a second stoichiometric silicon nitride (Si₃N₄) layer 423 are sequentially laminated. The charge trapping layer 420 of the previous embodiment has a double-layered structure.

More specifically, the first stoichiometric silicon nitride (Si₃N₄) layer 421 is disposed on the tunneling layer 410. The first stoichiometric silicon nitride (Si₃N₄) layer 421 has a thickness of about 20 Å to 60 Å. The ratio of silicon and nitrogen in the stoichiometric silicon nitride (Si₃N₄) layer 421 is approximately 1:1.2 to 1:1.5, and preferably about 1:1.33. The silicon-rich silicon nitride layer 422 has a thickness of about 20 Å to 60 Å. The ratio of silicon and nitrogen in the silicon-rich silicon nitride layer 422 is approximately 0.85:1 to 3:1, and preferably about 1:1. The second stoichiometric silicon nitride (Si₃N₄) layer 423 has a thickness of about 20 Å to 60 Å. The ratio of silicon and nitrogen in the stoichiometric silicon nitride (Si₃N₄) layer 423 is approximately 1:1.2 to 1:1.5, and preferably about 1:1.33. Accordingly, the total thickness of the charge trapping layer 420 is about 60 Å to 180 Å.

In this embodiment, the second stoichiometric silicon nitride (Si₃N₄) layer 423 is disposed between the silicon-rich silicon nitride layer 422 and the blocking layer 430, thereby preventing current leakage from the silicon-rich silicon nitride layer 422 to the blocking layer 430 and leading to an improvement in retention characteristics. In addition, the second stoichiometric silicon nitride (Si₃N₄) layer 423 more efficiently prevents backward tunneling from the control gate electrode 440 to the blocking layer 430. As a result, the thickness of the blocking layer 430 can be further reduced. According to another embodiment of the present invention, a first silicon oxynitride layer and a second silicon oxynitride layer may be used instead of the first stoichiometric silicon nitride (Si₃N₄) layer 421 and the second stoichiometric silicon nitride (Si₃N₄) layer 423, respectively.

A method for fabricating such a non-volatile memory device will be described in detail. Impurity regions 402 and a channel region 404 between the impurity regions 402 are formed in a substrate 400. A tunneling layer 410 is formed on the substrate 400. The tunneling layer 410 is formed of a silicon oxide layer having a thickness of about 20 Å to 60 Å. A charge trapping layer 420 is formed on the tunneling layer 410. The formation of the charge trapping layer 420 is performed by depositing a first stoichiometric silicon nitride (Si₃N₄) layer 421, a silicon-rich silicon nitride layer 422, and a stoichiometric silicon nitride (Si₃N₄) layer 423 sequentially on the tunneling layer 410. According to another embodiment of the present invention, a first silicon oxynitride layer and a second silicon oxynitride layer may be used instead of the first stoichiometric silicon nitride (Si₃N₄) layer 421 and the second stoichiometric silicon nitride (Si₃N₄) layer 423, respectively.

The formation of the first stoichiometric silicon nitride (Si₃N₄) layer 421 is performed using atomic layer deposition (ALD) or chemical vapor deposition (CVD). The thickness of the first stoichiometric silicon nitride (Si₃N₄) layer 421 is about 20 Å to 60 Å. The ratio of silicon to nitrogen in the first stoichiometric silicon nitride (Si₃N₄) layer 421 is approximately 1:1.2 to 1:1.5, and preferably about 1:1.33. The formation of the silicon-rich silicon nitride layer 422 is performed using atomic layer deposition (ALD) or chemical vapor deposition (CVD). The thickness of the silicon-rich silicon nitride layer 422 is about 20 Å to 60 Å. The ratio of silicon to nitrogen in the silicon-rich silicon nitride layer 422 is approximately 0.85:1 to 3:1, and preferably about 1:1. The ratio can be adjusted to a desired level by controlling a flow rate of a silicon source gas (e.g., dichlorosilane (DCS, SiCl₂H₂)), or a nitrogen source gas (e.g., NH₃). The formation of the first stoichiometric silicon nitride (Si₃N₄) layer 421 is performed using atomic layer deposition (ALD) or chemical vapor deposition (CVD). The formation of the second stoichiometric silicon nitride (Si₃N₄) layer 423 is performed using atomic layer deposition (ALD) or chemical vapor deposition (CVD). The thickness of the second stoichiometric silicon nitride (Si₃N₄) layer 423 is about 20 Å to 60 Å. The total thickness of the charge trapping layer 420 is about 60 Å to 180 Å. The ratio of silicon to nitrogen in the second stoichiometric silicon nitride (Si₃N₄) layer 423 is approximately 1:1.2 to 1:1.5, and preferably about 1:1.33.

After formation of the charge trapping layer 420 having a triple-layered structure, a blocking layer 430 is formed on the charge trapping layer 420. The blocking layer 430 includes an oxide layer deposited by chemical vapor deposition (CVD). Alternatively, the blocking layer 430 may include an aluminum oxide (Al₂O₃) layer to improve device characteristics. The blocking layer 430 is formed by depositing aluminum oxide (Al₂O₃) to a thickness of about 50 Å to 300 Å and subjecting the deposited aluminum oxide to densification by rapid thermal processing (RTP). The blocking layer 430 may be a high-dielectric (high-k) insulating layer, e.g., a hafnium oxide (HfO₂) layer, a hafnium aluminum oxide (HfAlO) layer, a zirconium oxide (ZrO₂) layer, or combinations thereof.

A control gate electrode 440 is formed on the blocking layer 430. If necessary, a low-resistance layer (not shown) may be formed on the control gate electrode 440. The control gate electrode 440 may be formed of a polysilicon layer or a metallic layer. When a polysilicon layer is used as the control gate electrode 440, the polysilicon layer may be doped with n-type impurities. When a metallic layer is used as the control gate electrode 440, the metallic layer may be a metallic layer having a work function of about 4.5 eV or higher. Examples of suitable metallic layers include a titanium nitride (TiN) layer, a tantalum nitride (TaN) layer, a hafnium nitride (HfN) layer, a tungsten nitride (WN) layer, and combinations thereof.

After the tunneling layer 410, the charge trapping layer 420 (including the first stoichiometric silicon nitride (Si₃N₄) layer 421 and the silicon-rich silicon nitride layer 422), the second stoichiometric silicon nitride (Si₃N₄) layer 423, the blocking layer 430, and the control gate electrode 440 are formed sequentially on the substrate 400, the resulting structure is subjected to common patternization using a hard mask layer pattern.

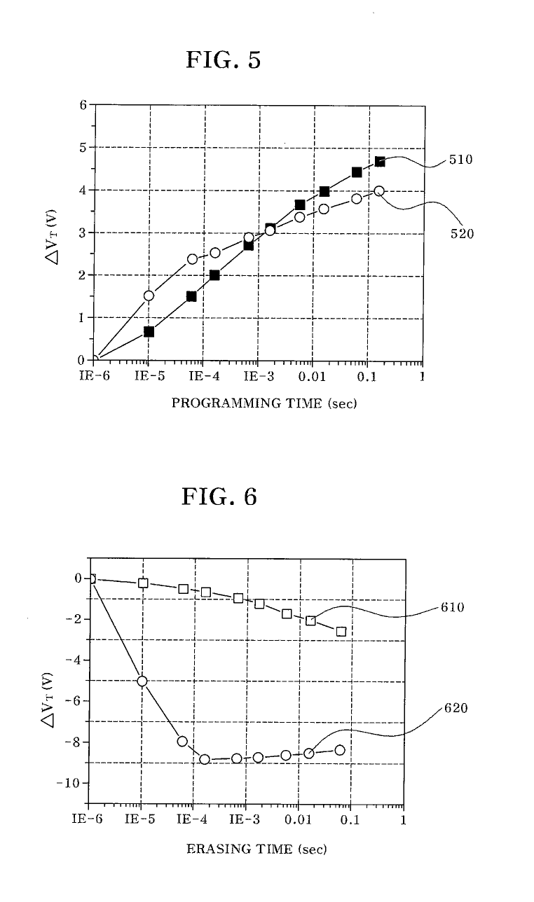

FIG. 5 is a graph showing programming characteristics of a non-volatile memory device having a charge trapping layer according to the present invention. Referring to FIG. 5, a memory device employing a conventional charge trapping layer which has a mono-layered structure including a stoichiometric silicon nitride layer (refer to curve denoted by “510”), and a memory device employing a charge trapping layer according to the present invention which has a double-layered structure including a stoichiometric silicon nitride layer and a silicon-rich silicon nitride layer (refer to curve denoted by “520”) show variations in similar delta threshold voltage (ΔV_{T}) states with the passage of programming time. The charge trapping layer according to the present invention exhibits relatively superior programming characteristics during an early programming time period.

FIG. 6 is a graph showing erasing characteristics of a non-volatile memory device having a charge trapping layer according to the present invention. Referring to FIG. 6, a memory device employing a charge trapping layer according to the present invention which has a double-layered structure including a stoichiometric silicon nitride layer and a silicon-rich silicon nitride layer (refer to curve denoted by “620”) shows a significant reduction in a delta threshold voltage (ΔV_{T}) with the passage of erasing time when compared to a memory device employing a conventional charge trapping layer which has a mono-layered structure including a stoichiometric silicon nitride layer (refer to curve denoted by “610”). It can be confirmed from this phenomenon that the charge trapping layer according to the present invention exhibits high erase speed and superior threshold voltage characteristics, compared to the conventional charge trapping layer.

What is claimed is:

1. A non-volatile memory device comprising:
a substrate;
a tunneling layer over the substrate;
a charge trapping layer comprising a stoichiometric silicon nitride layer and a silicon-rich silicon nitride layer over the tunneling layer;
a blocking layer over the charge trapping layer; and
a control gate electrode over the blocking layer.

2. The non-volatile memory device according to claim 1, wherein the tunneling layer is a silicon oxide (SiO₂) layer.

3. The non-volatile memory device according to claim 2, wherein a thickness of the silicon oxide (SiO₂) layer is approximately 20 Å to 60 Å.

4. The non-volatile memory device according to claim 1, wherein a thickness of the charge trapping layer is approximately 60 Å to 180 Å.

5. The non-volatile memory device according to claim 1, wherein the stoichiometric silicon nitride layer has a thickness of approximately 20 Å to 60 Å.

6. The non-volatile memory device according to claim 1, wherein the ratio of silicon and nitrogen in the stoichiometric silicon nitride layer is approximately 1:1.2 to 1:1.5.

7. The non-volatile memory device according to claim 1, wherein the ratio of silicon and nitrogen in the stoichiometric silicon nitride layer is approximately 1:1.33.

8. The non-volatile memory device according to claim 1, wherein the silicon-rich silicon nitride layer has a thickness of approximately 40 Å to 120 Å.

9. The non-volatile memory device according to claim 1, wherein the ratio of silicon and nitrogen in the silicon-rich silicon nitride layer is approximately 0.85:1 to 3:1.

10. The non-volatile memory device according to claim 1, wherein the ratio of silicon and nitrogen in the silicon-rich silicon nitride layer is approximately 1:1.

11. The non-volatile memory device according to claim 1, wherein the blocking layer includes an aluminum oxide (Al₂O₃) layer.

12. The non-volatile memory device according to claim 11, wherein the aluminum oxide (Al₂O₃) layer has a thickness of approximately 50 Å to 300 Å.

13. The non-volatile memory device according to claim 1, wherein the blocking layer includes a silicon oxide layer deposited by chemical vapor deposition (CVD).

14. The non-volatile memory device according to claim 1, wherein the blocking layer includes a hafnium oxide (HfO₂) layer, a hafnium aluminum oxide (HfAlO) layer, a zirconium oxide (ZrO₂) layer, or a combination thereof.

15. The non-volatile memory device according to claim 1, wherein the control gate electrode includes a metallic layer having a work function of about approximately 4.5 eV or higher.

16. The non-volatile memory device according to claim 15, wherein the metallic layer includes a titanium nitride (TiN) layer, a tantalum nitride (TaN) layer, a hafnium nitride (HfN) layer, a tungsten nitride (WN) layer, or a combination thereof.

17. A non-volatile memory device comprising:
a substrate;
a tunneling layer over the substrate;
a charge trapping layer comprising a first stoichiometric silicon nitride layer, a silicon-rich silicon nitride layer, and a second stoichiometric silicon nitride layer over the tunneling layer;
a blocking layer over the charge trapping layer; and
a control gate electrode over the blocking layer.

18. The non-volatile memory device according to claim 17, wherein the charge trapping layer has a thickness of approximately 60 Å to 180 Å.

19. The non-volatile memory device according to claim 17, wherein a thickness of the first stoichiometric silicon nitride layer is approximately 20 Å to 60 Å.

20. The non-volatile memory device according to claim 17, wherein the ratio of silicon and nitrogen in the first stoichiometric silicon nitride layer is approximately 1:1.2 to 1:1.5.

21. The non-volatile memory device according to claim 17, wherein the ratio of silicon and nitrogen in the first stoichiometric silicon nitride layer is approximately 1:1.33.

22. The non-volatile memory device according to claim 17, wherein the silicon-rich silicon nitride layer has a thickness of approximately 20 Å to 60 Å.

23. The non-volatile memory device according to claim 17, wherein the ratio of silicon and nitrogen in the silicon-rich silicon nitride layer is approximately 0.85:1 to 3:1.

24. The non-volatile memory device according to claim 17, wherein the ratio of silicon and nitrogen in the silicon-rich silicon nitride layer is approximately 1:1.

25. The non-volatile memory device according to claim 17, wherein the second stoichiometric silicon nitride layer has a thickness of approximately 20 Å to 60 Å.

26. The non-volatile memory device according to claim 17, wherein the ratio of silicon and nitrogen in the second stoichiometric silicon nitride layer is approximately 1:1.2 to 1:1.5.

27. The non-volatile memory device according to claim 17, wherein the ratio of silicon and nitrogen in the second stoichiometric silicon nitride layer is approximately 1:1.33.

28. The non-volatile memory device according to claim 17, wherein the blocking layer includes an aluminum oxide (Al₂O₃) layer.

29. The non-volatile memory device according to claim 28, wherein the aluminum oxide (Al₂O₃) layer has a thickness of approximately 50 Å to 300 Å.

30. The non-volatile memory device according to claim 17, wherein the blocking layer includes a silicon oxide layer deposited by chemical vapor deposition (CVD).

31. The non-volatile memory device according to claim 17, wherein the blocking layer includes a hafnium oxide (HfO₂) layer, a hafnium aluminum oxide (HfAlO) layer, a zirconium oxide (ZrO₂) layer, or a combination thereof.

32. The non-volatile memory device according to claim 16, wherein the control gate electrode includes a metallic layer having a work function of about 4.5 eV or higher.

33. The non-volatile memory device according to claim 32, wherein the metallic layer includes a titanium nitride (TiN) layer, a tantalum nitride (TaN) layer, a hafnium nitride (HfN) layer, a tungsten nitride (WN) layer, or a combination thereof.

34. A non-volatile memory device comprising:
a substrate;
a tunneling layer over the substrate;
a charge trapping layer comprising a silicon oxynitride layer and a silicon-rich silicon nitride layer over the tunneling layer;
a blocking layer over the charge trapping layer; and
a control gate electrode over the blocking layer.

35. A non-volatile memory device comprising:
a substrate;
a tunneling layer over the substrate;
a charge trapping layer comprising a first silicon oxynitride layer, a silicon-rich silicon nitride layer, and a second silicon oxynitride layer over the tunneling layer;
a blocking layer over the charge trapping layer; and
a control gate electrode over the blocking layer.

36. A method for fabricating anon-volatile memory device, the method comprising:
forming a tunneling layer over a substrate;
forming a stoichiometric silicon nitride layer over the tunneling layer;
forming a silicon-rich silicon nitride layer over the stoichiometric silicon nitride layer;
forming a blocking layer over the silicon-rich silicon nitride layer; and
forming a control gate electrode over the blocking layer.

37. The method according to claim 36, wherein the stoichiometric silicon nitride layer is formed to a thickness of approximately 20 Å to 60 Å.

38. The method according to claim 36, wherein the formation of the stoichiometric silicon nitride layer is performed by atomic layer deposition (ALD) or chemical vapor deposition (CVD).

39. The method according to claim 36, wherein the ratio of silicon to nitrogen in the stoichiometric silicon nitride layer is approximately 1:1.2 to 1:1.5.

40. The method according to claim 36, wherein the ratio of silicon to nitrogen in the stoichiometric silicon nitride layer is approximately 1:1.33.

41. The method according to claim 36, wherein the silicon-rich silicon nitride layer is formed to a thickness of approximately 40 Å to 120 Å.

42. The method according to claim 36, wherein the ratio of silicon to nitrogen in the silicon-rich silicon nitride layer is approximately 0.85:1 to 3:1.

43. The method according to claim 36, wherein the ratio of silicon to nitrogen in the silicon-rich silicon nitride layer is approximately 1:1.

44. The method according to claim 36, wherein the blocking layer comprises a high-dielectric insulting layer.

45. The method according to claim 36, wherein the blocking layer comprises an oxide layer deposited by chemical vapor deposition (CVD).

46. The method according to claim 38, further comprising:
performing annealing process on the blocking layer.

47. A method for fabricating a non-volatile memory device, the method comprising:
forming a tunneling layer over a substrate;
forming a first stoichiometric silicon nitride layer over the tunneling layer;
forming a silicon-rich silicon nitride layer over the first stoichiometric silicon nitride layer;
forming a second stoichiometric silicon nitride layer over the silicon-rich silicon nitride layer;
forming a blocking layer over the second stoichiometric silicon nitride layer; and
forming a control gate electrode over the blocking layer.

48. The method according to claim 47, wherein the first stoichiometric silicon nitride layer is formed to a thickness of approximately 20 Å to 60 Å.

49. The method according to claim 47, wherein the formation of the stoichiometric silicon nitride layer is performed by atomic layer deposition (ALD) or chemical vapor deposition (CVD).

50. The method according to claim 47, wherein the ratio of silicon to nitrogen in the first stoichiometric silicon nitride layer is approximately 1:1.2 to 1:1.5.

51. The method according to claim 47, wherein the ratio of silicon to nitrogen in the first stoichiometric silicon nitride layer is approximately 1:1.33.

52. The method according to claim 47, wherein the silicon-rich silicon nitride layer is formed to a thickness of approximately 20 Å to 60 Å.

53. The method according to claim 47, wherein the ratio of silicon to nitrogen in the silicon-rich silicon nitride layer is approximately 0.85:1 to 3:1.

54. The method according to claim 47, wherein the ratio of silicon to nitrogen in the silicon-rich silicon nitride layer is approximately 1:1.

55. The method according to claim 47, wherein the second stoichiometric silicon nitride layer is formed to a thickness of approximately 20 Å to 60 Å.

56. The method according to claim 47, wherein the formation of the second stoichiometric silicon nitride layer is performed by atomic layer deposition (ALD) or chemical vapor deposition (CVD).

57. The method according to claim 47, wherein the ratio of silicon to nitrogen in the second stoichiometric silicon nitride layer is approximately 1:1.2 to 1:1.5.

58. The method according to claim 47, wherein the ratio of silicon to nitrogen in the second stoichiometric silicon nitride layer is approximately 1:1.33.

59. The method according to claim 47, wherein the blocking layer comprises a high-dielectric insulting layer.

60. The method according to claim 47, wherein the blocking layer comprises an oxide layer deposited by chemical vapor deposition (CVD).

61. The method according to claim 47, further comprising:
performing annealing process on the blocking layer.

62. The method according to claim 47, wherein the control gate electrode comprises a metallic layer.

63. A method for fabricating a non-volatile memory device, the method comprising:
forming a tunneling layer over a substrate;
forming a first silicon oxynitride layer over the tunneling layer;
forming a silicon-rich silicon nitride layer over the first silicon oxynitride layer;
forming a blocking layer over the silicon-rich silicon nitride layer; and
forming a control gate electrode over the blocking layer.

64. A method for fabricating a non-volatile memory device, the method comprising:
forming a tunneling layer over a substrate;
forming a first silicon oxynitride layer over the tunneling layer;
forming a silicon-rich silicon nitride layer over the first silicon oxynitride layer;
forming a second silicon oxynitride layer over the silicon-rich silicon nitride layer;
forming a blocking layer over the second silicon oxynitride layer; and
forming a control gate electrode over the blocking layer.
